(19) United States
(12) Patent Application Publication
(10) Pub. No.: US 2013/0089943 A1
(43) Pub. Date: Apr. 11, 2013

(54) METHOD OF MANUFACTURING A SOLAR CELL

(71) Applicants: Yen-Yu Chen, Taipei City (TW); Wei-Shuo Ho, Taipei City (TW); Yu-Hung Huang, Taipei City (TW); Y.Y. Chen, Taipei City (TW); Chee Wee Liu, Taipei City (TW)

(72) Inventors: Yen-Yu Chen, Taipei City (TW); Wei-Shuo Ho, Taipei City (TW); Yu-Hung Huang, Taipei City (TW); Y.Y. Chen, Taipei City (TW); Chee Wee Liu, Taipei City (TW)

(73) Assignee: NATIONAL TAIWAN UNIVERSITY, Taipei (TW)

(21) Appl. No.: 13/440,951

(22) Filed: Apr. 5, 2012

(30) Foreign Application Priority Data
Oct. 6, 2011 (TW) 100136326

(51) Int. Cl. H01L 31/0232

(52) U.S. Cl. 438/72; 257/E31.127

(57) ABSTRACT

An embodiment of the present disclosure provides method of manufacturing a solar cell. The method comprises the steps of providing a silicon substrate, forming a P-N junction structure in the silicon substrate, forming an oxide layer for passivating the surface defect of the substrate that has a low reflectivity for AM1.5G solar spectrum, and forming a plurality of metal electrodes on the silicon substrate.

### CROSS-REFERENCE TO RELATED APPLICATION(S)

This application claims priority to Taiwan Patent Application No. 1001363264 entitled “METHOD OF MANUFACTURING A SOLAR CELL,” which was filed on Oct. 6, 2011, and is hereby incorporated by reference in its entirety.

### FIELD OF THE EMBODIMENTS

The present disclosure relates to a method of manufacturing a solar cell.

### BACKGROUND

Because of the energy crisis that is a result of the depletion of fossil fuels, development of clean energy technology has become an important research issue around the world. Renewable energy sources such as solar power, wind power, biomass power, and water power have been developed. In particular, the technology of solar cells is more mature than others and is often considered the most feasible method of renewable energy, which complies with requirements of safety and environmental protection.

Known solar cells are manufactured by forming a P-N junction on a silicon chip through a diffusion process, depositing an anti-reflection layer with plasma enhanced chemical vapor through a deposition process, and forming a conductive electrode through a metalizing process so as to generate electrical current when absorbing light energy.

In order to reduce the manufacturing costs of the solar cell, the thickness of the silicon chip needs to be minimized. However, when the thickness of the silicon chip is minimized, the effect of minority carrier recombination resulting from surface defects on the silicon chip may decrease light current while increase dark current, that may affect photovoltaic conversion efficiency of the solar cell.

By raising the photovoltaic conversion efficiency of the solar cell, the passivation process is a key point of fabrication procedure, which is in a manner of reducing defect density of an interface or generating surface electric field effect. Additionally, the passivation process also affects the photovoltaic conversion efficiency of the solar cell.

Presently, silicon nitride (SiNₓ) is a significant improvement in anti-reflection technology for mass production. However, the thickness of the anti-reflection may affect the current and metal electrode. It may change the absorption range of the optical spectrum for the solar cell, and may change the sinter temperature of the metal electrode if the thickness of the anti-reflection is either too thick or too thin. Therefore, there is a need for an improved technology for manufacturing method for a solar cell.

### SUMMARY

The present application describes a method of manufacturing a solar cell, which improve the photovoltaic conversion efficiency of the solar cell by forming an oxide layer having both a passivation effect and an anti-reflection effect.

In one embodiment, the method of manufacturing the solar cell comprises the steps of providing a silicon substrate, forming a P-N junction structure in the silicon substrate, forming an oxide layer for passivating the surface defect of the substrate, which has a low reflectivity for the AM1.5G solar spectrum, and forming a plurality of metal electrodes on the silicon substrate.

In another embodiment, the method of manufacturing the solar cell comprises the steps of providing a silicon substrate, implanting one or more dopants into the silicon substrate for forming a P-N junction structure in the silicon substrate, forming an oxide layer on the silicon substrate as a passivation and anti-reflection layer by a deposition process, and forming a plurality of metal electrodes on the silicon substrate.

In another embodiment, the method of manufacturing the solar cell comprises the steps of providing a silicon substrate, implanting dopants into the silicon substrate for forming a P-N junction structure in the silicon substrate, forming an oxide layer on the silicon substrate for passivating defects at light receiving surface of the silicon substrate, wherein the silicon dioxide layer has low reflectivity at a predetermined band, and forming a plurality of metal electrodes on the silicon substrate.

At least one advantage of the disclosed method of manufacturing the solar cell is simple and quicker manufacturing by forming the oxide layer having passivation effect and anti-reflection effect via one step. Thus, the cost and time consumed for manufacturing the solar cell may be reduced significantly.

The foregoing is a summary and shall not be construed to limit the scope of the claims. The operations and devices disclosed herein may be implemented in a number of ways, and such changes and modifications may be made without departing from this disclosure and its broader aspects. Other aspects, inventive features, and advantages of the disclosure, as defined solely by the claims, are described in the non-limiting detailed description set forth below.

### BRIEF DESCRIPTION OF THE DRAWINGS

FIGS. 1A through 1C are cross sectional views illustrating the steps for manufacturing a solar cell, in accordance with one embodiment of the present disclosure;

FIG. 2 is a flow chart showing a method of manufacturing a solar cell, in accordance with one embodiment of the present disclosure; and

FIG. 3 is a current density-voltage characteristic curve of a solar cell, in accordance with one embodiment of the present disclosure.

### DETAILED DESCRIPTION OF EMBODIMENTS

The following description is of the best-contemplated mode of carrying out the disclosure. This description is made for the purpose of illustrating the general principles of the disclosure and should not be taken in a limiting sense. The scope of the disclosure is best determined by reference to the appended claims.

Reference will be made in detail to the present embodiments, examples of which are illustrated in the accompanying drawings. Wherever possible, the same reference numbers are used in the drawings and the description to refer to the same or like parts. In the drawings, the shape and thickness of one embodiment may be exaggerated for clarity and convenience. This description will be directed in particular to elements forming part of, or cooperating more directly with, the apparatus in accordance with the present disclosure. It is to be understood that elements not specifically shown or described may take various forms well known to those skilled in the art. Further, when a layer is referred to as being on another layer or “on” a substrate, it may be directly on the other layer or on the substrate, or intervening layers may also be present.

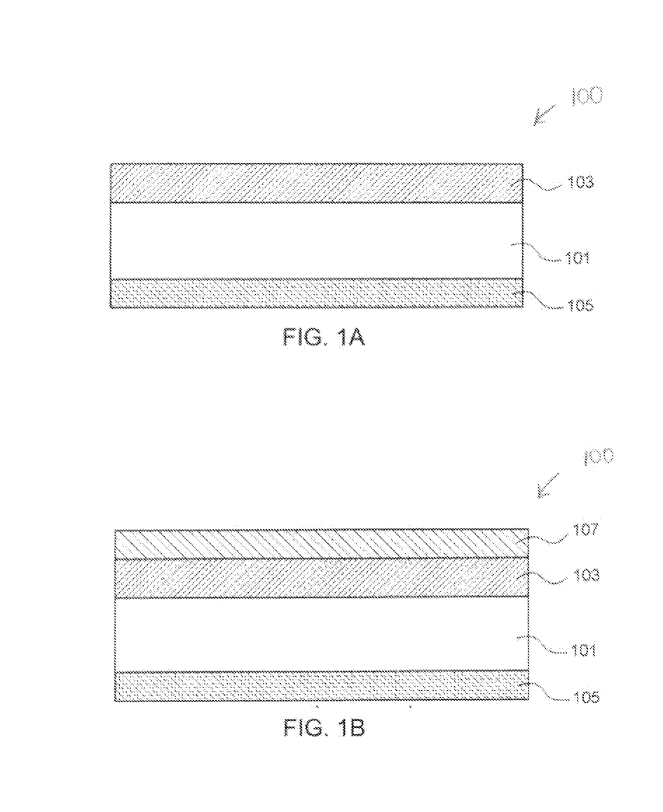

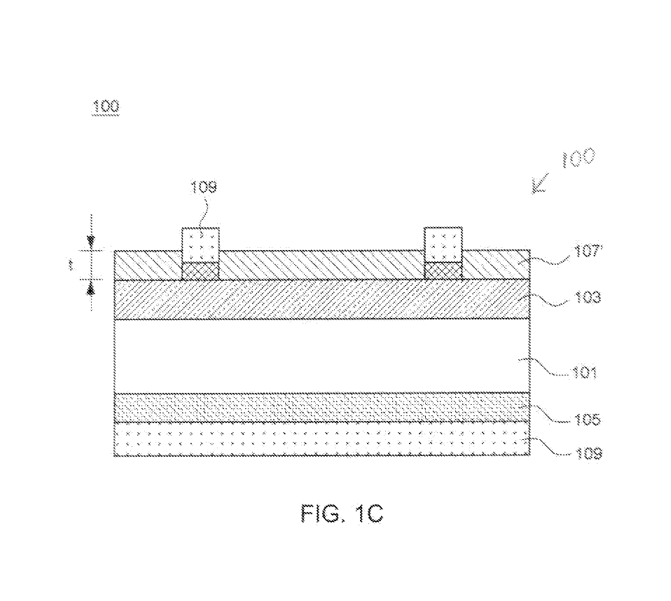

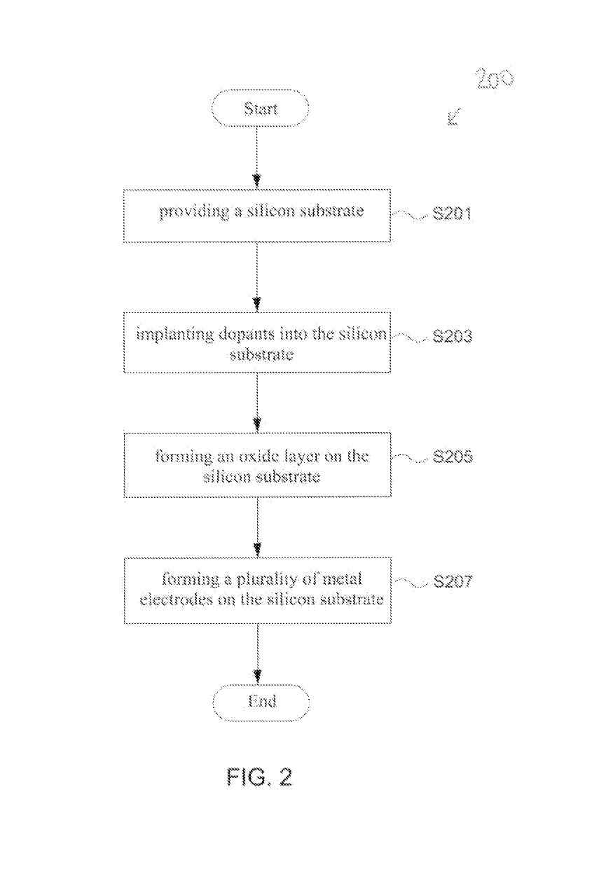

The present application describes a method of manufacturing a solar cell 100. FIGS. 1A through 1C depict cross sectional views illustrating the steps for m manufacturing the solar cell 100 in accordance with one embodiment of the present disclosure. It is worthy to notice that the method of manufacturing the solar cell 100 of the present disclosure may comprise other components, but in order to simplify the figures and descriptions, only the basic and/or essential structures are depicted and described, such depictions and descriptions not being restrictive of the scope of the present disclosure. In conjunction with FIGS. 1A through 1C, FIG. 2 is a flow chart depicting a method 200 of manufacturing a solar cell in accordance with one embodiment of the present disclosure.

As shown in FIGS. 1A through 2, the method 200 of manufacturing the solar cell 100 comprises the following steps. First, a semiconductor substrate 101 is provided at step S201. The semiconductor substrate 101 is a silicon substrate in this embodiment, where the material of the silicon substrate 101 may be polycrystalline silicon or monocrystalline silicon. A crystal orientation of the silicon substrate 101 may be {100}, {110} or {111}, as described by the Miller index. The silicon substrate 101 may be doped with P-type or N-type dopants.

Next, a P-N junction structure is formed in the silicon substrate 101 by performing an implantation process on the silicon substrate 101, such as a diffusion process or an ion implantation at step S203. More specifically, P-type dopants or N-type dopants are implanted in a light receiving surface (upper surface) and a back light surface (bottom surface) of the silicon substrate 101 to form an emitter 103 at a side of the light receiving surface and form a back surface filed (BSF) 105 at a side of the back light surface, as shown in FIG. 1A. Therefore, the silicon substrate 101 has a p⁺nn⁺ structure or a n⁺pp⁺ structure, where the p⁺ (p-type dopant) and the n⁺ (n-type dopant) may be amorphous silicon, polycrystalline silicon, or monocrystalline silicon.

Next, an oxide layer 107 is formed on the silicon substrate 101 for passivating defects at light receiving surface of the silicon substrate 101 at step S205, as shown in FIG. 1B. One technological characteristic of the disclosed embodiment is that the oxide layer 107 is formed as both a passivation and an anti-reflection layer of the solar cell 100 in a single process. Hence, the manufacturing process of the solar cell 100 may be simplified for large-area fabrication, and the thickness of a single layer of the oxide layer 107 may be substantially thinner for reducing the rate of light absorption while also increasing the photovoltaic conversion efficiency of the solar cell 100.

In an embodiment, the oxide layer 107 may be formed by a furnace annealing process, an atomic layer deposition process, a physical vapor deposition process, a chemical vapor deposition process, a coating process, or a rapid thermal annealing process.

More specifically, the thickness t of the oxide layer 107 is designed according to a depth of activated dopants during the manufacturing process of the oxide layer 107 in this embodiment. Therefore, the oxide layer 107 may have low or very small reflectivity at a predetermined band such as AM1.5G solar spectrum, such that a rate of light received into the light receiving surface of the solar cell 100 may be increased and a photovoltaic conversion efficiency of the solar cell 100 may also increased.

In an embodiment, a desired thickness t of the oxide layer 107, as shown in FIG. 1C, may be obtained by controlling an annealing time and an annealing temperature. In general, the longer the annealing time or the higher the annealing temperature, the thicker the thickness t of the oxide layer 107. For example, the thickness t of the oxide layer 107 comprising as silicon dioxide may be between approximately 3 nm and 120 nm after demonstrating at nitrogen, argon, oxygen, trichloroethane, or mixed gas ambient for approximately 1 to 15 minutes of annealing time at an annealing temperature in the range about of 800 degrees Celsius to 1000 degrees Celsius.

In an embodiment, the oxide layer 107 may be silicon nitride (Si₃N₄), silicon dioxide (SiO₂), aluminum trioxide (Al₂O₃), hydrogenated amorphous silicon carbon (a-SiC: H), amorphous silicon (a-Si), or titanium dioxide (TiO₂) formed by a deposition process.

Finally, a plurality of metal electrodes 109 are formed on the silicon substrate 101 at step S207, as shown in FIG. 1C. A pattern of the metal electrodes 109 may be defined by photoresist coating, photolithography, and developing processes. Additionally, the metal electrodes 109 are formed by a sputtering process, a thermal evaporation process, an e-beam evaporation process, or a screen printing annealing process on a patterned oxide layer 107′ in a manner of point contact or full contact on the back light surface of the solar cell 100. The metal electrodes 109 may made from nickel (Ni), copper (Cu), silver (Ag), aluminum (Al), titanium (Ti), or platinum (Pt). However, the manufacturing process of the metal electrodes 109 is not restricted by the above-mentioned embodiment.

In an embodiment, the method of manufacturing the solar cell 100 further comprises the step of performing low-temperature annealing to the solar cell 100, resulting in better Ohmic contact and good surface passivation. For example, the solar cell 100 may be demonstrated at nitrogen, argon, hydrogen, or mixed gas ambient for 30 minutes at an annealing temperature in the range of 300 degrees Celsius to 500 degrees Celsius.

Accordingly, the thickness t of the oxide layer 107 may be designed by controlling various parameters of the manufacturing process for obtaining desired passivation and anti-reflection effects. The sequence of the procedure of the present disclosure is not restricted by the above-mentioned embodiment.

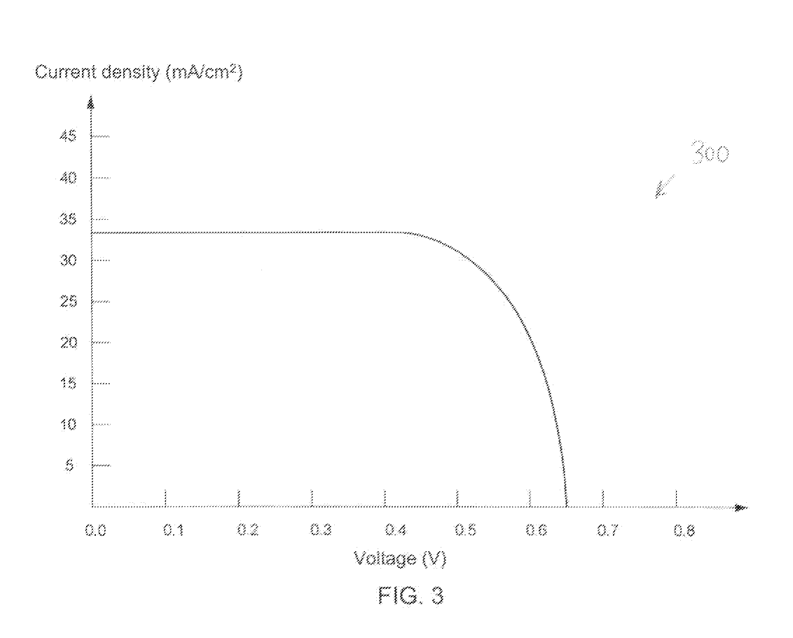

FIG. 3 is a current density-voltage characteristic curve 300 of a solar cell in accordance with an embodiment of the present disclosure. FIG. 3 illustrates the current density associated with voltage of the solar cell 100 under the AM1.5G solar spectrum. An open voltage Voc of the solar cell 100 with the oxide layer 107 is approximately 0.631 volt (V).

Based on the above-mentioned method of manufacturing the solar cell, the oxide layer may be formed on the silicon substrate in one step. The oxide layer may be regarded as not only a passivation layer, but also an anti-reflection layer for the solar cell without requiring an additional procedure to fabricate the anti-reflection layer. Therefore, the manufacturing process of the solar cell may be simplified and the manufacturing costs may be reduced, such that the manufacturing processes may dominate industry applications of semiconductors. Further, other electronic or optical devices may utilize this technique to reduce defects produced in the manufacturing process and improve the characteristics of electricity or light.

As may be used herein, the terms “substantial,” “substantially,” “approximate,” and “approximately” provide an industry-accepted tolerance for its corresponding term and/or relativity between items. Such an industry-accepted tolerance ranges from less than one percent to ten percent and corresponds to, but is not limited to, component values, angles, et cetera. Such relativity between items ranges between less than one percent to ten percent.

While various embodiments in accordance with the principles disclosed herein have been described above, it should be understood that they have been presented by way of example only, and not limitation. Thus, the breadth and scope of this disclosure should not be limited by any of the above-described exemplary embodiments, but should be defined only in accordance with any claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 CFR 1.77 or otherwise to provide organizational cues. These headings shall not limit or characterize the embodiment(s) set out in any claims that may issue from this disclosure. Specifically and by way of example, although the headings refer to a “Technical Field,” the claims should not be limited by the language chosen under this heading to describe the so-called field. Further, a description of a technology in the “Background” is not to be construed as an admission that certain technology is prior art to any embodiment(s) in this disclosure. Neither is the “Summary” to be considered as a characterization of the embodiment(s) set forth in issued claims. Furthermore, any reference in this disclosure to “invention” in the singular should not be used to argue that there is only a single point of novelty in this disclosure. Multiple embodiments may be set forth according to the limitations of the multiple claims issuing from this disclosure, and such claims accordingly define the embodiment(s), and their equivalents, that are protected thereby. In all instances, the scope of such claims shall be considered on their own merits in light of this disclosure, but should not be constrained by the headings set forth herein.

1. A method of manufacturing a solar cell, the method comprising:
providing a silicon substrate;
implanting one or more dopants into the silicon substrate for forming a P-N junction structure in the silicon substrate;
forming an oxide layer on the silicon substrate as a passivation and anti-reflection layer by a furnace annealing process; and
forming a plurality of metal electrodes on the silicon substrate.

2. The method according to claim 1, wherein the step of forming the P-N junction structure comprises a diffusion process or an ion implantation.

3. The method according to claim 1, wherein the oxide layer comprises a silicon dioxide layer for passivating defects at a light receiving surface of the silicon substrate.

4. The method according to claim 1, wherein the furnace annealing process is demonstrated at nitrogen, argon, oxygen, trichloroethane, or mixed gas ambient.

5. The method according to claim 4, wherein the furnace annealing process at an annealing temperature in the range of about 800 degrees Celsius to 1000 degrees Celsius.

6. The method according to claim 5, wherein the furnace annealing process uses an annealing time of about 1 to 15 minutes.

7. The method according to claim 6, wherein the thickness of the oxide layer is between about 3 nm and 120 nm.

8. The method according to claim 1, wherein the plurality of metal electrodes on the silicon substrate are fabricated by screen printing, sputter, and evaporation.

9. A method of manufacturing a solar cell, comprising:
providing a silicon substrate;
implanting one or more dopants into the silicon substrate for forming a P-N junction structure in the silicon substrate;
forming an oxide layer on the silicon substrate as a passivation and anti-reflection layer by a deposition process; and
forming a plurality of metal electrodes on the silicon substrate.

10. The method according to claim 9, wherein the deposition process comprises an atomic layer deposition process, a physical vapor deposition process, or a chemical vapor deposition process.

11. The method according to claim 9, wherein the oxide layer includes silicon nitride, silicon dioxide, aluminum oxide, amorphous silicon carbides, amorphous silicon, or titanium dioxide for passivating defects at a light receiving surface of the silicon substrate, and the oxide layer has low reflectivity at a predetermined band.

12. A method of manufacturing a solar cell, comprising:
providing a silicon substrate;
implanting one or more dopants into the silicon substrate for forming a P-N junction structure in the silicon substrate;
forming an oxide layer on the silicon substrate for passivating defects at a light receiving surface of the silicon substrate, wherein the oxide layer has low reflectivity at a predetermined band; and
forming a plurality of metal electrodes on the silicon substrate.

13. The method according to claim 12, wherein the step of forming the oxide layer comprises a furnace annealing process.

14. The method according to claim 12, wherein the step of forming the oxide layer comprises an atomic layer deposition process, a physical vapor deposition process, or a chemical vapor deposition process.

15. The method according to claim 12, wherein the step of forming the oxide layer comprises a coating process.

16. The method according to claim 12, wherein the step of forming the oxide layer comprises a rapid thermal annealing process.

17. The method according to claim 12, wherein the step of forming the metal electrodes comprises a sputtering process, a thermal evaporation process, an e-beam evaporation process, or a screen printing annealing process.

18. The method according to claim 17, wherein the metal electrodes are formed on a back light surface of the silicon substrate in a manner of point contact or full contact.

19. The method according to claim 12, further comprising forming an anti-reflection layer on the oxide layer.

20. The method according to claim 19, wherein the step of forming the anti-reflection layer comprises a coating process or a vapor deposition process.
